(19) United States
(12) Patent Application Publication
(10) Pub. No.: US 2016/0300729 A1
(43) Pub. Date: Oct. 13, 2016

(54) Methods and Apparatus for Deuterium Anneal of Multi-Layered Semiconductor Structure

(71) Applicant: Peregrine Semiconductor Corporation, San Diego, CA (US)

(72) Inventors: Sinan Goktepeli, San Diego, CA (US); Richard Hammond, Hillcrest, CA (US)

(21) Appl. No.: 14/683,914

(22) Filed: Apr. 10, 2015

(51) Int. Cl. H01L 21/324; H01L 29/06; H01L 23/66; H01L 29/04; H01L 23/31; H01L 23/29; H01L 29/78; H01L 29/10

(52) U.S. Cl. CPC H01L 21/324; H01L 29/78; H01L 29/0649; H01L 29/1079; H01L 29/045; H01L 23/3171; H01L 23/29; H01L 23/66; H01L 2223/6627

(57) ABSTRACT

Methods and apparatus for passivation of semiconductor interfaces by deuterium annealing are described. Harmonic improvements after deuterium annealing of a SOI semiconductor device with a trap-rich layer was demonstrated. Secondary ion mass spectroscopy after deuterium anneal shows a deuterium rich interface layer at the BOX-trap-rich layer interface of a MOSFET semiconductor device.

### TECHNICAL FIELD

Various embodiments described herein relate generally to methods and product for an improved semiconductor device performance, such as harmonic performance. Such semiconductor devices include metal-oxide-semiconductor (“MOS”) field effect transistors (“FET”s), devices with MOSFETs fabricated on Semiconductor-On-Insulator (“SOI”) substrates, and trap-rich SOT transistors, among others.

### BACKGROUND

It is desirable to improve interface electrical performance for semiconductor devices including metal-oxide-semiconductor (“MOS”) field effect transistors (“FET”s), and particularly to MOSFETs fabricated on Semiconductor-On-Insulator (“SOI”) and Silicon-On-Sapphire (“SOS”) substrates, the present invention provides methods and apparatus for same.

### SUMMARY

Herein described are various aspects of disclosure describing the utility of a deuterium anneal over a trap-rich region under a semiconductor device.

According to a first aspect, a semiconductor device is disclosed, comprising: a trap-rich region; a buried oxide layer on the trap-rich layer; a semiconductor layer on the buried oxide layer; and a deuterium rich region at an interface between the buried oxide layer and the trap-rich layer.

According to a second aspect, a method of deuterium annealing a semiconductor device is disclosed, comprising: providing a semiconductor device comprising: a trap-rich layer; a buried oxide layer on the trap-rich layer; a semiconductor layer on the buried oxide layer; and an interface between the buried oxide layer and the trap-rich layer; and contacting the semiconductor device with deuterium gas at a temperature of at least 20° C. and a pressure of at least 1 atmosphere for an interval of time.

Further aspects of the disclosure are presented herein.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A illustrates schematically an exemplary structure of a bulk silicon MOSFET transistor and FIG. 1B illustrates an exemplary silicon-oxide interface chemical structure.

FIG. 2A illustrates an exemplary structure of a SOI transistor with three silicon-oxide interfaces and FIG. 2B illustrates an exemplary structure of a coplanar waveguide.

FIG. 3A illustrates an exemplary structure of an RF trap-rich SOI transistor which contains dangling bonds at the polycrystalline grains boundaries besides the polycrystalline silicon-oxide interfaces and FIG. 3B illustrates an exemplary corresponding structure with a coplanar waveguide.

FIG. 4 illustrates exemplary concentration profiles for silicon and deuterium ions with depth.

FIG. 5 illustrates an exemplary cross section for a MOSFET device.

### DETAILED DESCRIPTION

Throughout this description, embodiments and variations are described for the purpose of illustrating uses and implementations of the inventive concept. The illustrative description should be understood as presenting examples of the inventive concept, rather than as limiting the scope of the concept as disclosed herein. Embodiments of the present disclosure are directed to methods and apparatus for passivation of semiconductor interfaces by deuterium annealing.

It is an object of the present invention to improve the harmonic performance of a semiconductor device by a deuterium anneal under the oxide layer. In one embodiment, the passivation of dangling bonds and charge traps within the trap-rich layer of a semiconductor device by deuterium annealing improves its harmonic performance as shown by the RF linearity results. The semiconductor device can include, but is not limited to, silicon CMOS, MOSFET, SOI, and SOS. The semiconductor device can include a trap-rich region in the substrate.

As used herein, “a trap-rich region” is meant as a region of high resistivity material with a high density of traps or defects that reduces the carrier lifetimes of the charge carriers. A “trap-rich layer” as used herein refers to a trap-rich region that forms a layer structure. A trap-rich region on the top of the substrate layer can effectively reduce parasitic surface conduction. In one embodiment the trap-rich region is made of a layer of polycrystalline silicon. In another embodiment, the trap-rich region is localized under a device and does not extend beyond the outer boundaries of source and drain regions laterally.

Embodiments of trap-rich materials can include oxygen doped polycrystalline silicon (“SIPOS”), amorphous silicon, polycrystalline silicon, rapid thermal anneal (“RTA”) crystallized polysilicon, and nanocrystalline silicon. The embodiments of trap-rich materials can also include polycrystalline/amorphous silicon carbide (SiC), which has a higher thermal conductivity than most other trap-rich materials and, therefore, will extract heat from the device more efficiently and reduce any increase in device resistance due to self-heating during operation.

In one embodiment, the trap-rich region has a bulk resistivity in a range of 1,000 to 10,000 Ohm-cm. In another embodiment, the trap-rich region has a resistivity profile in a range of 2,000 to 8,000 Ohm-cm.

In one embodiment, the trap-rich region is a layer with a thickness in a range of 0.1 to 10 micrometers. In another embodiment, the trap-rich region is a layer with a thickness in the range of 0.5 to 2 micrometers.

A dangling bond as used herein refers to an unsatisfied valence on an immobilized atom. In one embodiment, a dangling bond is present in a silicon atom at the poly-silicon grain boundary. In another embodiment, a dangling bond is present at the gate oxide to silicon interface. In one embodiment, a dangling bond is present at the buried oxide-substrate silicon interface. In another embodiment, a dangling bond is present at the buried oxide to silicon interface. The presence of dangling bonds can facilitate the current flow between the source and drain at these interfaces. The dangling bonds in a substrate act as trapped charges and affect device performance.

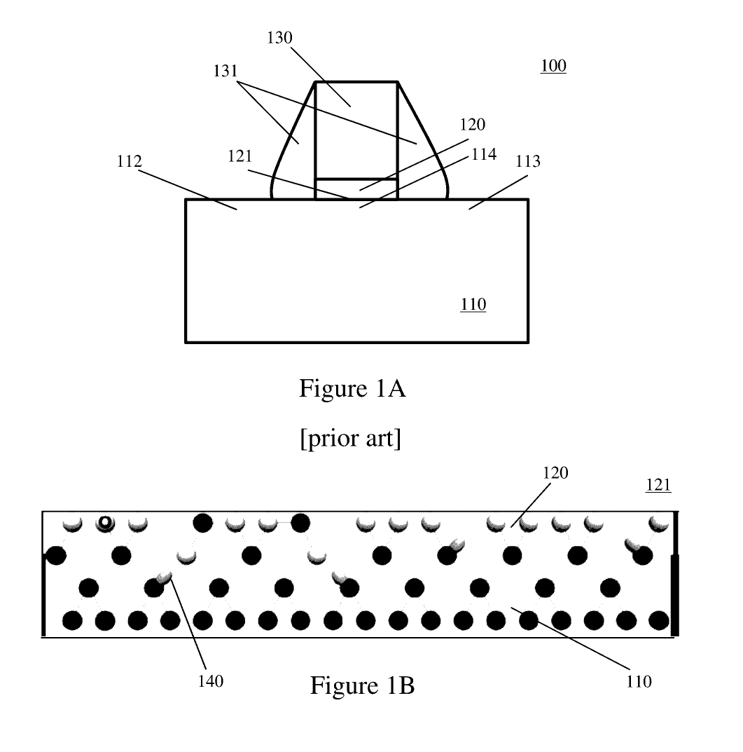

A typical bulk silicon MOSFET transistor is shown in FIG. 1A. The bulk silicon MOSFET transistor 100 includes a silicon substrate 110 and a dielectric layer on the silicon substrate which is a gate oxide layer 120 as shown, which can be formed through oxidation of the silicon substrate. A source area 112 and a drain area 113 are characterized by the presence of a dopant which can be acceptors from Group III or donors from Group V elements. An insulating sidewall spacer 131 separates the gate from the source and drain area.

A silicon atom with a dangling bond is capable of forming a complete covalent bond. Without being bound by the theory, it is understood that silicon dangling bonds are capable of covalent bond formation with deuterium and thus become passivated. The passivation by deuterium in effect neutralizes the trapped charge. As described herein, a deuterium anneal passivates dangling bonds at the oxide-silicon interface and improves device performance.

An interface 121 is formed between the gate oxide layer 120 and channel region 114 of the substrate 110. FIG. 1B shows a schematic of the chemical structure typical of such a silicon oxide-silicon interface 121 in which the silicon crystal is shown in a (100) plane. Passivation of dangling bonds 140 at the interface 121 of the gate oxide of the device by deuterium anneal improves device reliability and performance. Deuterium annealing results in the formation a deuterium rich interface region or layer. By “deuterium rich” as used herein is meant a region of a material including a multi-layered structure that has a detectably concentrated amount of deuterium above a baseline. The vertical extent of the deuterium rich region/layer depends upon the characteristics of the substrate and the anneal. Example extents include 0.2 micrometers from the interface 121 or 2.0 micrometers from the interface 121. The horizontal extent can also be controlled such that the deuterium rich region can form a layer spanning the entire substrate 110, or only a portion of the substrate 110, for example a portion no larger than the horizontal extent of the transistor device above the region.

In one embodiment, deuterium anneal is performed on a device or a wafer that has been previously annealed with hydrogen. In another embodiment, deuterium anneal is performed on a device or a wafer that has not been previously hydrogen annealed.

In one embodiment, deuterium anneal is performed on a wafer prior to device fabrication. In another embodiment, deuterium anneal is performed on a wafer after device fabrication.

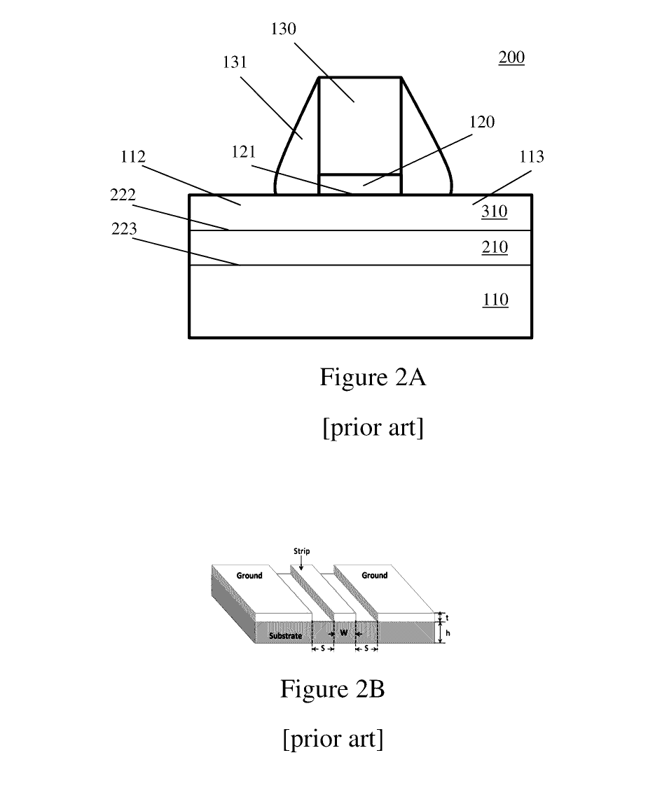

A typical semiconductor-on-insulator (“SOT”) structure is shown in FIG. 2A. A SOI transistor of FIG. 2A differs from bulk silicon transistor as exemplified in FIG. 1 due to the insulating buried oxide (“BOX”) 210 within the silicon substrate 110. The insulation by BOX 210 improves device performance, for example, by reducing leakage current and parasitic device capacitance.

As shown in FIG. 2A, dangling bonds are present in three distinct oxide-silicon interfaces 121, 222, and 223. Gate oxide interface 121 is formed between the gate oxide 120 and silicon 310. Top BOX-silicon interface 222 is formed between buried oxide 210 and active silicon layer 310. Bottom BOX-silicon interface 223 is formed between BOX 210 and silicon substrate 110.

In one embodiment, the buried-oxide is made of sapphire to give silicon-on-sapphire (“SOS”) devices. Such a SOS device can be advantageously used for high-performance radio frequency (RF) and radiation-sensitive applications.

During device operation, a charge layer can build up at the interface 223 under the BOX 210. The charge layer can severely degrade the harmonic performance of the RF devices on the SOT substrates.

Referring to FIG. 2B, an exemplary coplanar waveguide is shown, with a strip of width W and height t separated on each side by trenches of width S from the ground planes, on a substrate of height h.

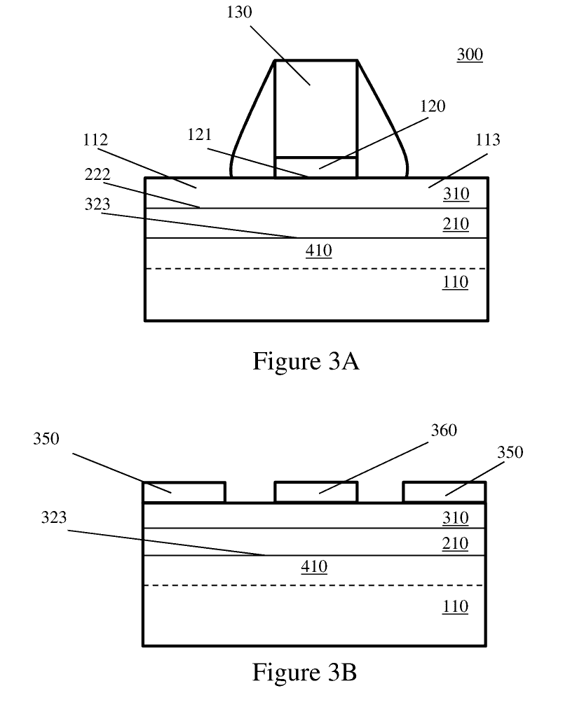

Referring to FIG. 3A, an example structure of an RF trap-rich SOI transistor 300 is shown schematically. The trap-rich SOI transistor 300 is similar to SOI 200 of FIG. 2 with an additional trap-rich region 410 beneath the BOX layer 210. The trap-rich region 410 disturbs charge conduction at the lower buried oxide-silicon interface 323 and significantly enhances the device RF harmonic performance compared to SOI transistors.

The trap-rich region 410 can be made of a layer of polycrystalline silicon which contains dangling bonds at the polycrystalline grains boundaries as well as at the buried oxide-polycrystalline interface 323. In addition, the trap-rich region may include a modified region of the substrate in which the charge traps are introduced by disrupting the crystalline substrate by means of ion-implantation, for example. Passivation, near the interface 323, of these dangling bonds with deuterium reduces charge traps and enhances the harmonic performance of such devices at radio frequencies.

FIG. 3B shows an exemplary coplanar waveguide, consisting of a center conductive strip 360 between two ground planes 350, utilizing the deuterium anneal at the interface 323 between a trap-rich region 410 in the substrate 110 and a BOX layer 210 over the substrate 110.

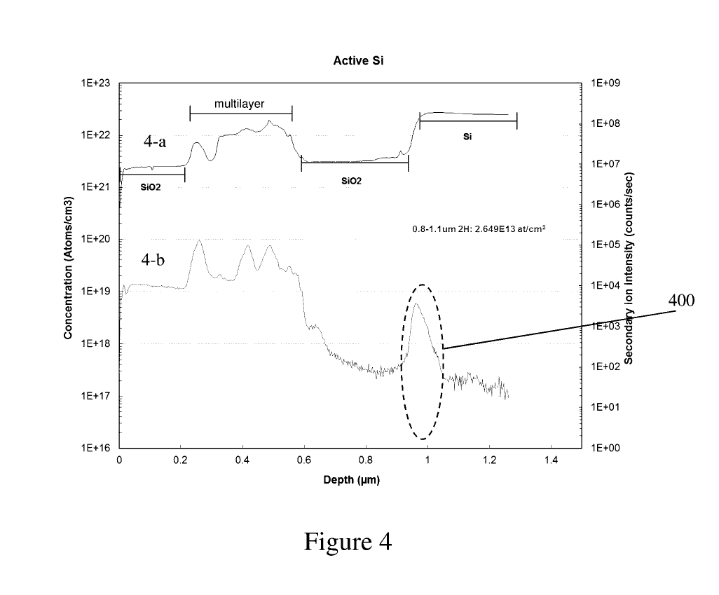

FIG. 4 shows concentration profiles for silicon (top trace 4-a) and deuterium (bottom trace 4-b) ions with depth (in microns) as measured by the secondary ion mass spectroscopy (“SIMS”) including a deuterium peak area 400 within a subsection of 0.8-1.1 micron depth range at the BOX-trap-rich layer interface of a MOSFET semiconductor device, with a peak of about 5×10¹⁸ atoms/cm³ over a baseline of 1−3×10¹⁷ atoms/cm³. The sheet density of the deuterium peak is 2.649×10¹³ atoms/cm² in the same 0.8-1.1 micron depth range.

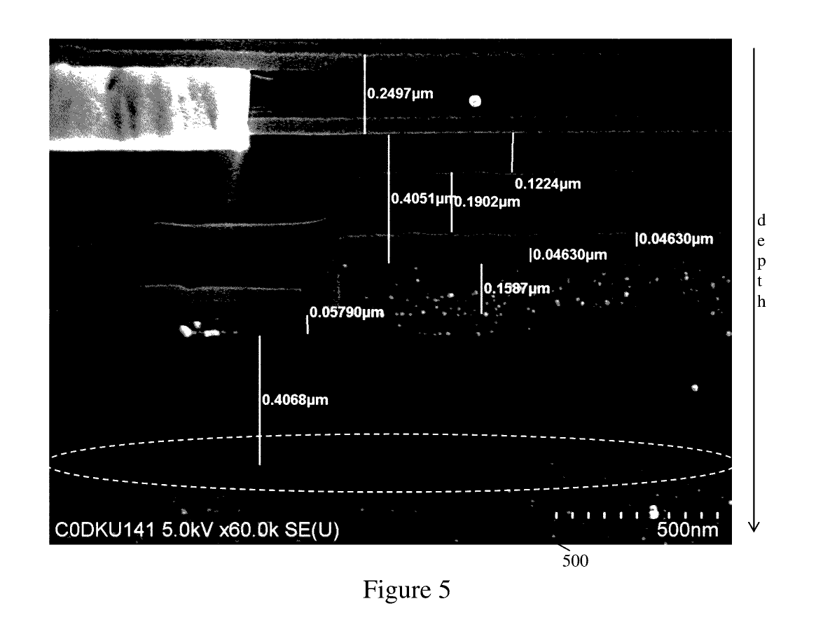

FIG. 5 shows a scanning electron microscope (“SEM”) of a cross section for a MOSFET device including an annotated depth range 500 that corresponds to the deuterium peak area 400 of FIG. 4 at the BOX-trap-rich layer interface.

### EXAMPLES

In one embodiment, the deuterium anneal was performed after device fabrication. The deuterium anneal was performed in a high pressure furnace under the following conditions in Table 1. The device could be previously hydrogen annealed, but it is envisioned that the process can be performed with devices that are not pre-annealed (i.e. only having deuterium anneal). Even with a hydrogen pre-anneal of a device, the deuterium can displace the hydrogen such that a majority of the passivation in the device is from deuterium (i.e., there is more deuterium than hydrogen in the region). As is shown in Table 1, the oxygen content of the silicon substrate can be low or high.

TABLE 1
Experimental Matrix

| Split | Temperature | Duration | Pressure | Oxygen |
|---|---|---|---|---|
| (#) | (° C.) | (min) | (atm) | Content |
| 1 | 400 | 30 | 20 | Low |
| 2 | 400 | 30 | 20 | High |
| 3 | 400 | 60 | 20 | Low |
| 4 | 400 | 60 | 20 | High |
| 5 | 425 | 30 | 20 | Low |
| 6 | 425 | 30 | 20 | High |

As used herein, ppma refers to parts per million atoms. In one embodiment, the value for low oxygen content is about 5 N-ppma. In another embodiment, the value for high oxygen content is about 15 N-ppma. The N-ppma values are based on the ASTM-F1188 standard for determination of the interstitial oxygen content of single crystal silicon.

Results of testing the CPW harmonic performance for Split #1 (i.e., D₂anneal at 400 ° C. for 30 minutes at 20 atmospheres with “Low” oxygen) are summarized in Table 2. The coplanar waveguide is an electrical transmission line consisting of 3 parallel, conducting metal strips as shown in FIG. 2B which have the substrate made of Split #1. An RF signal is applied to the central strip and the harmonic distortion of the signal is measured to assess the RF performance of the underlying substrate. Typically the length of the strips is 1 mm. In one embodiment the width (W) of the strip is about 25 microns and the separation (S) between the strips is about 25 microns.

In one embodiment the tested device is a transistor. The gate length (Lg) of the transistor was 0.2 μm. For the ‘ON’ harmonic measurement, transistors with a gate width of 0.5 mm were used; whilst for the ‘OFF’ harmonic measurement, transistors with a gate width of 2 mm were used instead. All harmonic results were measured in dBm units. As is shown in Table 2, a larger negative number implies an improved harmonic performance.

TABLE 2

| | 2^{nd} Harmonic | | | 3^{rd} Harmonic | | |
|---|---|---|---|---|---|---|
| | No D2 | D2 | En- | No D2 | D2 | En- |
| | Anneal | Anneal | hancement | Anneal | Anneal | hancement |
| Coplanar | −101.7 | −103.3 | −1.5 | −113.8 | −119.1 | −5.4 |
| Wave- | | | | | | |
| guide | | | | | | |
| (CPW) | | | | | | |
| Transistor | −79.5 | −80.4 | −0.9 | −81.4 | −86.4 | −5.0 |
| ON | | | | | | |
| Transistor | −101.1 | −101.4 | −0.3 | −80.4 | −81.6 | −1.2 |
| OFF | | | | | | |

The effect of 400° C. anneal duration on the harmonic performance is shown in Table 3 for Split #1 and 3.

Both the substrate harmonic performance (CPW measurement) and the device harmonics are improved after deuterium anneal as shown in the result for Split #1.

The deuterium anneal duration affects the harmonic performance of the substrate. A comparison of Split #1 and 3 shows that a 60 minute anneal gives a better substrate harmonic improvement (“enhancement”) than a 30 minute anneal with all other conditions being the same.

TABLE 3
2^{nd} Harmonic

| | | 30 min | 60 min | |
|---|---|---|---|---|
| Split | No D2 anneal | D2 Anneal | D2 Anneal | Enhancement |
| 1 | −101.7 | −103.3 | | −1.5 |
| 3 | −100.8 | | −102.7 | −1.9 |

3^{rd} Harmonic

| | | 30 min | 60 min | |
|---|---|---|---|---|
| Split | No anneal | Anneal | Anneal | Enhancement |
| 1 | −113.8 | −119.1 | | −5.4 |
| 3 | −113.6 | | −120.7 | −7.1 |

Applications that can include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems can further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments can include a number of methods.

It can be possible to execute the activities described herein in an order other than the order described. Various activities described with respect to the methods identified herein can be executed in repetitive, serial, or parallel fashion.

The accompanying drawings that form a part hereof show, by way of illustration and not of limitation, specific embodiments in which the subject matter can be practiced. The embodiments illustrated are described in sufficient detail to enable those skilled in the art to practice the teachings disclosed herein. Other embodiments can be utilized and derived therefrom, such that structural and logical substitutions and changes can be made without departing from the scope of this disclosure. This disclosure, therefore, is not to be taken in a limiting sense, and the scope of various embodiments is defined only by the appended claims, along with the full range of equivalents to which such claims are entitled.

Such embodiments of the inventive subject matter can be referred to herein, individually or collectively, by the term “invention” merely for convenience and without intending to voluntarily limit the scope of this application to any single invention or inventive concept, if more than one is in fact disclosed. Thus, although specific embodiments have been illustrated and described herein, any arrangement calculated to achieve the same purpose can be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

An Abstract of the disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In the foregoing disclosure, various features are grouped together in a single embodiment for the purpose of streamlining the disclosure. This method of disclosure is not to be interpreted to require more features than are expressly recited in each claim. Rather, inventive subject matter can be found in less than all features of a single disclosed embodiment. Thus the following claims are hereby incorporated into the disclosure herein, with each claim standing on its own as a separate embodiment.

1. A semiconductor device comprising:
a trap-rich region;
a buried oxide layer on the trap-rich region;
a semiconductor layer on the buried oxide layer; and
a deuterium rich region at an interface between the buried oxide layer and the trap-rich region.

2. The device of claim 1, wherein the trap-rich region comprises polycrystalline silicon.

3. The device of claim 1, wherein the buried oxide comprises silicon dioxide.

4. The device of claim 1 further comprising a substrate layer under the buried oxide layer and wherein the trap-rich region comprises a region of the substrate layer having a more heavily disrupted crystal structure than other parts of the substrate layer.

5. The device of claim 4, wherein the substrate layer comprises silicon.

6. The device of claim 5, wherein the substrate layer comprises a silicon (100) plane.

7. The device of claim 4, wherein the trap-rich region spans only a portion of a width of the substrate layer.

8. The device of claim 1, wherein the deuterium rich region is within 2 μm above and below the interface.

9. The device of claim 8, wherein the deuterium rich region is within 0.2 μm above and below the interface.

10. The device of claim 1, wherein the deuterium rich interface layer has a half peak width of less than 1 micron by secondary ion mass spectroscopy.

11. The device of claim 10, wherein the half peak width is less than 0.1 micron by secondary ion mass spectroscopy.

12. The device of claim 1, wherein the deuterium rich interface layer comprises more deuterium than hydrogen.

13. The device of claim 1, further comprising a transistor over the buried oxide layer.

14. The device of claim 1, further comprising a coplanar waveguide over the buried oxide layer.

15. The device of claim 1, wherein the trap-rich region comprises at least one of polycrystalline silicon carbide and amorphous silicon carbide.

16. A method of deuterium annealing a semiconductor device comprising:
providing a semiconductor device wafer comprising:
a trap-rich region;
a buried oxide layer on the trap-rich region;
a semiconductor layer on the buried oxide layer; and
an interface between the buried oxide layer and the trap-rich region; and
contacting the semiconductor device wafer with deuterium gas at a temperature of at least 20° C. and a pressure of at least 1 atmosphere for an interval of time.

17. The method of claim 16, wherein the temperature is in a range between 200° C. to 500° C.

18. The method of claim 17, wherein the temperature is in a range between 300° C. to 450° C.

19. The method of claim 18, wherein the temperature is 400° C.

20. The method of claim 16, wherein the pressure is in a range between 5 atmospheres to 30 atmospheres.

21. The method of claim 20, wherein the pressure is 20 atmospheres.

22. The method of claim 16, wherein the interval of time is at least 5 minutes.

23. The method of claim 22, wherein the interval of time is at least 30 minutes.

24. The method of claim 23, wherein the interval of time is at least 60 minutes.

25. The method of claim 16, wherein the semiconductor device wafer further comprises a hydrogen anneal at the interface.

26. The method of claim 25, wherein a region at the interface comprises more deuterium than hydrogen.

27. The method of claim 16, wherein the trap-rich region comprises at least one of polycrystalline silicon carbide and amorphous silicon carbide.
